(19) United States
(12) Patent Application Publication
(10) Pub. No.: US 2008/0157117 A1
(43) Pub. Date: Jul. 3, 2008

(54) Insulated gate bipolar transistor with enhanced conductivity modulation

(76) Inventors: Ty R. McNutt, Columbia, MD (US); Ginger G. Walden, W. Lafayette, IN (US); Marc E. Sherwin, Catonsville, MD (US)

Correspondence Address: ANDREWS KURTH LLP;Intellectual Property Department, Suite 1100, 1350 I Street, NW, Washington, DC, 20005, US

(21) Appl. No.: 11/646,346

(22) Filed: Dec. 28, 2006

(51) Int. Cl. H01L 29/74; H01L 21/332

(52) U.S. Cl. 257/133; 438/135; 257/E21.388; 257/E29.112

(57) ABSTRACT

A insulated gate bipolar transistors (IGBT) having an enhanced modulation layer provides reduced on-state power dissipation and better conductivity modulation than conventional devices. The IGBT includes an enhanced modulation layer disposed within a portion of the n− doped drift layer, in a n-type device, or p− doped drift layer, in a p-type device. The enhanced modulation layer contains a higher carrier concentration than the n− or p− doped drift layer. If the IGBT device is in an on state, the enhanced modulation layer decreases a size of a depletion region formed around the p well body region or n well body region. In a n-type enhanced modulation layer IGBT, electrons, traveling from the n+ region towards the emitter, are spread laterally and uniformly in the n− doped drift layer. In a p-type enhanced modulation layer IGBT, holes, traveling from the p+ region towards the emitter, are spread laterally and uniformly in the p− doped drift layer.

The invention was made under a contract with an agency of the United States Government, contract number N00014-05-C-0203.

### FIELD OF THE INVENTION

The invention relates generally to electronic devices, specifically to an insulated gate bipolar transistor with enhanced conductivity modulation and methods of making same.

### BACKGROUND OF THE INVENTION

Metal oxide field effect transistors (MOSFETs) and insulated gate bipolar transistors (IGBT) are typically manufactured using silicon. The MOSFET is often used for lower voltages (e.g., <600 V) while an IGBT can be used for voltages between, for example, 600 V and 6.5 kV. One of the reasons for using an IGBT over a MOSFET device is the trade-off between on-state losses and switching losses. The n-channel MOSFET is a uni-polar device, generally relying on electrons to carry the current. When designing a MOSFET to handle high blocking voltages (off state blocking), thick, lightly doped semiconductor layers are used. Although using thick, lightly doped semiconductor layers allows the device to handle high blocking voltages, this configuration also leads to high drift resistance and poor on-state losses.

The n-channel IGBT, on the other hand, is a bipolar device that utilizes conductivity modulation in a thick drift region. During reverse blocking, the layer thickness and doping must be low enough to allow the blocking voltage to be dropped across the drift region. During the on-state, the low carrier concentration and the thick base layer of an IGBT is modulated by minority carriers (holes), injected from the lower p+ emitter. The injected hole density can be very high (orders of magnitude higher than the background electron density) and will effectively lower the on-state resistance.

A single IGBT device may contain a plurality of IGBT cells. However, conventional IGBT cell configuration techniques limit the number of IGBT cells that can be fabricated on a single wafer. In addition, the conventional configuration also limits conductivity modulation of the device.

### SUMMARY OF THE INVENTION

A insulated gate bipolar transistors (IGBT) having an enhanced modulation layer provides reduced on-state power dissipation and better conductivity modulation than conventional devices. The IGBT includes an enhanced modulation layer disposed within a portion of the n− doped drift layer, in a n-type device, or p− doped drift layer, in a p-type device. The enhanced modulation layer contains a higher carrier concentration than the n− or p− doped drift layer. If the IGBT device is in an on state, the enhanced modulation layer decreases a size of a depletion region formed around the p well body region or n well body region. In a n-type enhanced modulation layer IGBT, electrons, traveling from the n+ region towards the emitter, are spread laterally and uniformly in the n− doped drift layer. In a p-type enhanced modulation layer IGBT, holes, traveling from the p+ region towards the emitter, are spread laterally and uniformly in the p− doped drift layer.

### BRIEF DESCRIPTION OF THE DRAWINGS

FIG. 1 illustrates a IGBT cell with an enhanced modulation layer, in accordance with an embodiment.

FIG. 2 illustrates a pair of contiguous IGBT cells with an enhanced modulation layer, in accordance with an embodiment.

FIG. 3 is a graph showing an on-state current density versus different cell spacing at various current spreading layer dopings, in accordance with an embodiment.

FIG. 4 is a graph showing the ratio of an electric field in the cell spacing region of an enhanced modulation layer IGBT, in accordance with an embodiment.

FIG. 5 is a flow chart illustrating a method for fabricating an enhanced modulation layer IGBT, in accordance with an embodiment.

### DETAILED DESCRIPTION

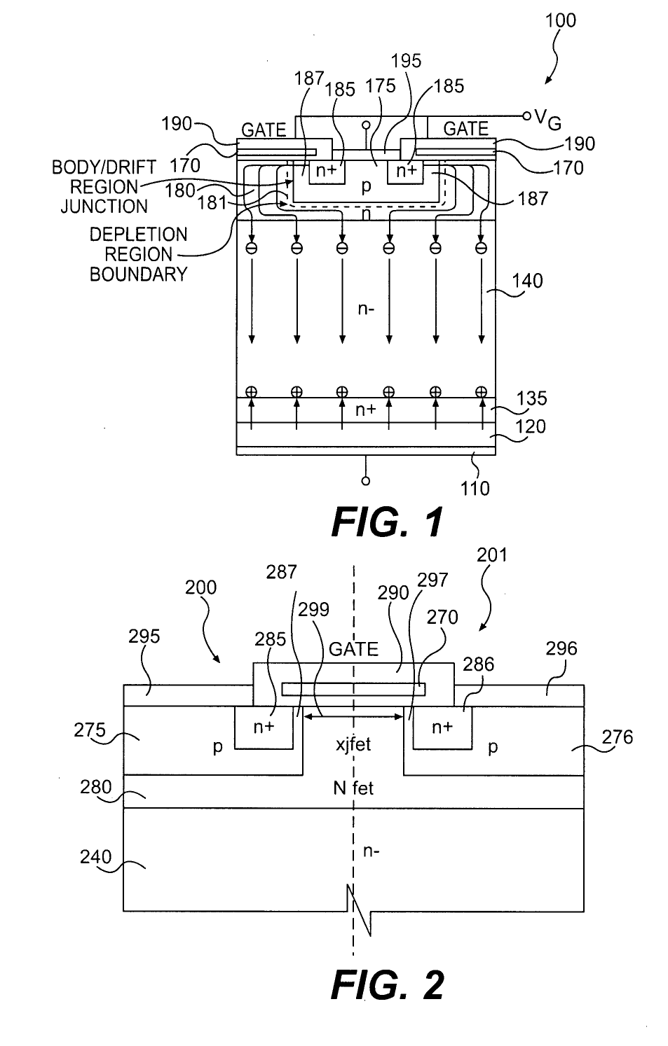

FIG. 1 illustrates a single cell of a n-type insulated gate bipolar transistor (IGBT) cell 100 incorporating an enhanced modulation layer. An IGBT device may include a plurality of IGBT cells fabricated on a single silicon carbide (SiC) wafer, for example. Other materials, such as silicon, gallium nitride (GaN), gallium arsenide (GaAs) may be used for device fabrication.

The IGBT cell 100 includes a emitter 110, a collector 195, and a gate 170. The collector 195 and emitter 110 may be metal electrodes, and the gate 170 may be a poly-silicon gate. The emitter 110 is coupled to p+ doped injecting layer 120. A n− doped drift layer 140 is disposed on the p+ doped injecting layer 120. A p well body region 175 is disposed on the n− doped drift layer 140. The n− doped drift layer 140 is located between the p+ doped injecting layer 120 and the p well body region 175. As shown, n+ regions 185 are disposed in the p well body region 175. A channel 187 is formed in the surface of the p well 175 under the gate 170, between the N+and the depletion region 181. The gate 170 is disposed over a portion of the p well body region 175 surrounded by a gate insulating film or oxide 190. The gate insulating film or oxide 190 may be a silicon dioxide (SiO₂). The gate 170 may be poly silicon or other material. The collector 195 is in contact with the n+ regions 185 and a portion of the p well body region 175. Optionally, the IGBT cell may include a n+ doped buffer layer 135 disposed between the p+ doped injecting layer 120 and the n− doped drift layer 140.

In an embodiment, the IGBT cell 100 includes an enhanced modulation layer 180 (or current spreading layer) disposed on top of the n− doped drift layer 140. The enhanced modulation layer 180 may contain a higher carrier concentration than the n− doped drift layer. For example, the enhanced modulation layer 180 may contain a n− doping of 5×10¹⁶/cm³ in an n-type IGBT, which is approximately ten to one-hundred times the doping of the n− doped drift layer 140. As will be describe below in detail, the distance between n+ regions of contiguous IGBT cells may also be optimized to improve the operation of the IGBT CELL 100 and provide enhanced modulation.

The on/off state of the device is controlled by the gate voltage V_{G}. For an n-channel device, if the voltage applied to the gate contact 170, with respect to the collector 195, is less than the threshold voltage Vₜₕ, then no inversion layer is created under the gate 170 and the IGBT cell 100 is in the off state. In the off state, the only current to flow across the n− doped drift layer 140 will be a small leakage current.

The forward breakdown voltage is determined by the breakdown voltage of the p-n junction at the p well body region 175 and the n− doped drift layer 140. This breakdown voltage may be dependent on the doping of the lower-doped side of the p-n junction, i.e., n− doped drift layer 140. Conventionally, the n− doped drift layer 140 is lightly doped, on the order of 1×10¹⁴ to 1×10¹⁶ depending on the blocking voltage. The n− doped drift layer 140 lightly doped to support high blocking voltages. The lower doping results in a wider depletion region that surrounds p well body region 175, near the p-n junction between the p well body region 175 and the n− doped drift layer 140. The lower doping and wider depletion region in the n− doped drift layer 140 region results in a lower maximum electric field, in the off state, in the depletion region at a given blocking voltage. Also, the light doping leads to high resistivity in sections of the n− doped drift layer 140 that are not fully conductivity modulated during on state operation. Thus, in conventional IGBTs, the larger depletion region surrounding the p well body region 175 coupled with the high resistance drift layer 140 results in increased on-state power dissipation and decreased conductivity modulation.

A depletion region forms across a p-n junction, such as the junction at the p well body region 175 and the n− doped drift layer 140, when the junction is in thermal equilibrium, i.e. things are in a steady state. Electrons and holes will diffuse into regions with lower concentrations of electrons and holes. An n-type semiconductor has an excess of free electrons; and p-type has an excess of holes. Therefore when n− doped and p− doped pieces of semiconductor are placed together to form a junction, electrons will diffuse into the p side and holes will diffuse into the n side. However when a hole and an electron come into contact, they eliminate each other through recombination. This bares the donor atoms adjacent to the depletion region, which are now charged ions. The ions are positive on the n side and negative on the p side, creating an electric field that counteracts the continued diffusion of charge carriers. When the electric field is sufficient to repel incoming holes and electrons, the depletion region reaches its equilibrium width. Integrating the electric field in the depletion region gives what is known as the built-in potential (also called the junction voltage or barrier voltage). Under reverse bias (p negative with respect to n) this potential is increased, further widening the depletion region. Forward bias (p positive with respect to n) narrows the depletion region, making the p-n junction barrier lower increasing the probability of the flow of charge carriers across the junction. The depletion region is so named because it is void of all majority carriers. In other words, the recombination of holes and electrons at the p-n junction causes the region to become depleted of mobile charge.

An embodiment of the present invention includes an enhanced modulation layer 180 grown on top of the n− doped drift layer 140 and surrounding the p well body region 175, as shown in FIG. 1. The doping of the enhanced modulation layer may be between 5×10¹⁵/cm³ to 1×10¹⁷/cm³, and the thickness may be at or between 0.1 and 1.5 μm. In operation, the enhanced modulation layer IGBT 100 is turned on by increasing the gate voltage V_{G} so that it is greater than the threshold voltage Vₜₕ of the IGBT cell 100. This results in an inversion layer forming under the gate 170, which provides a channel linking the source n+ regions 185 to the drift region of the device. Electrons are then injected from the source into the n-drift region 140. The enhanced modulation layer 180 decreases the size of the depletion region 181 formed around the p well body region 175, as shown. This permits the electrons exiting the channel 187 to uniformly extend out in the enhanced modulation layer 180, underneath the p well body region 175 due to the smaller depletion region, and the lower spreading resistance due to the increased dopant density. Also, the electrons, traveling from the n+ regions 185 towards the emitter 110, are spread laterally and uniformly in the n− doped drift layer 140, as shown in FIG. 1. This uniform, lateral spreading of electrons in the drift layer 140 of the IGBT cell 100 provides lower on-state resistance, reduced on-state power dissipation, and enhanced conductivity modulation over conventional devices, such as conventional IGBTs, MOSFETs, SITs (static induction transistor). As shown in FIG. 1, the uniform, lateral spreading of electrons in the drift layer 140 causes the uniform injection of holes into the n− doped drift region 140 at the p-n junction formed at the p+ doped injecting layer 120 and the n− doped drift layer.

As described above, the enhanced modulation layer 180 decreases the size of the depletion region 181. A smaller depletion region 181 leads to more uniform spreading of electrons. The higher doping of the enhanced modulation layer 180 leads to an area of lower resistivity than the thick lightly doped drift region 140, thus a lower spreading resistance results due to the increased dopant density. Because of the lower resistivity of the enhanced modulation layer 180, electrons will travel laterally, and injection into the drift region 140 is very uniform.

The optional n+ doped buffer layer 135, as shown in FIG. 1, may be incorporated in an embodiment, referred to as a punch-through design, to prevent the depletion region 181 from extending right to the p+ doped injecting layer 120. The inclusion of the n+ doped buffer layer 135 may reduce the reverse blocking capability of the IGBT cell 100 as this is dependent on the breakdown voltage of junction between the p+ doped injecting layer 120 and the n+ doped buffer layer 135, which is reverse biased under reverse voltage conditions. However, the n+ doped buffer layer 135 reduces the thickness of the n− doped drift region 140, thus reducing IGBT on-state losses. Also, the n+ doped buffer layer 135 design can be used to trade off switching speed of the device with on-state losses by adjusting the doping and lifetime in the region. The stored charge in the on-state can be swept into the n+ doped buffer layer 135 during switching, thus reducing the time for the device to turn-off, however this can raise the on-state voltage drop slightly.

The electric field in the IGBT cell 100 for breakdown in the blocking state is greater in heavier doped material, it is possible to design the enhanced modulation layer thickness and doping so that has minimal effect to the operation of the device in blocking mode. Also, the spacing of the xjfet region of FIG. 2 can be narrowed to keep the electric field in the SiO₂ low during reverse bias operation.

Although the above described IGBT cell is described as an n-type/n-channel device, the enhanced modulation layer configuration, as described herein, applies equally to an p-type/p-channel IGBT. In a p-type/p-channel IGBT cell, the dopings and electrode polarities are reversed. A p-type/p-channel IGBT cell (not shown) includes a emitter, collector, and a gate. The collector and emitter may be metal electrodes, and the gate may include an oxide, such as a SiO₂. The emitter is coupled to n+ doped injecting layer. A p− doped drift layer is disposed on the n+ doped injecting layer. A n well body region is disposed on the p− doped drift layer. The p− doped drift layer is located between the n+ doped injecting layer and the n well body region. P+ regions are disposed in the first n well body region. The gate is disposed over a portion of the first n well body region with a gate insulating film interposed there between. The gate insulating film may be poly silicon or other insulating material. The collector is in contact with the p+ regions and a portion of the first n well body region. The IGBT cell 100 includes an enhanced modulation layer disposed within a portion of the p− doped drift layer and surrounds the n well body region. The enhanced modulation layer may contain a higher carrier (i.e., holes) concentration than the p− doped drift layer. Optionally, the IGBT cell may include a p+ doped buffer layer disposed between the n+ doped injecting layer and the p− doped drift layer 140.

When the p-type enhanced conductivity modulation IGBT 100 device is turned on, holes are injected from p+ region. The laterally and uniformly spread holes in the p− doped drift layer holes attract electrons injected from the n+ doped injecting layer. The injected electrons are spread laterally and uniformly in the p− doped drift layer. This uniform, lateral spreading of holes and/or holes in the drift layer of the p-type IGBT cell provides lower on-state resistance, reduced on-state power dissipation, and enhanced conductivity modulation over conventional devices.

FIG. 2 illustrates a pair of contiguous n-type IGBT cells 200 and 201, separated by the dotted line. The contiguous n-type IGBT cells 200 and 201 include an enhanced modulation layer 280 in accordance with an embodiment. As described above, these cells can also be p-type IGBT cells. A IGBT device may include a plurality of IGBT cells, configured contiguously as shown in FIG. 2, that may be fabricated or located on a single substrate or wafer depending on the device characteristics. The IGBT cells may be fabricated in a variety of configurations, such as linear, hexagonal, or square geometries, on a wafer or substrate. Only a portion of the IGBT cells are shown in FIG. 2. The IGBT cells 200 and 201 may include the same components and operation as described with respect to the IGBT cell 100, shown in FIG. 2 and described above.

The IGBT cells 200, 201 include a The IGBT cell include emitters (omitted), collectors 295, 296, and a gate 270. The collectors and emitters may be metal electrodes, and the gate may be include an oxide, such as a silicon oxide (SiO₂). The cells 200, 201 include a p+ doped injecting layer (omitted). A n− doped drift layer 440 is disposed on the p+ doped injecting layer. The IGBT cells 200, 201 include p well body regions 275, 276, respectively, disposed on the n− doped drift layer 240. A channel 287 is formed in the surface of the p well 275 under the gate 270 and a channel 297 is formed in the surface of the p well 276 under the gate 270. An enhanced modulation layer 280 is grown on the n− doped drift layer 240, as shown. The IGBT cells 200, 201, include n+ regions 285, 286 disposed in their p well body regions 275, 276.

FIG. 2 illustrates that, using an enhanced modulation layer, the horizontal distance xjfet 299, between p well body regions 275, 276, of contiguous IGBT cells, can be reduced. This reduction in the xjfet distance 299 permits more IGBT cells to be fabricated in a given area or permit a IGBT device to become more compact. The xjfet distance 299 may also be referred to as the cell spacing. In an embodiment, the xjfet distance 299 may range from less than 0.5 μm to 4 μm, or more. The xjfet distance 299 can be varied depending on device characteristics.

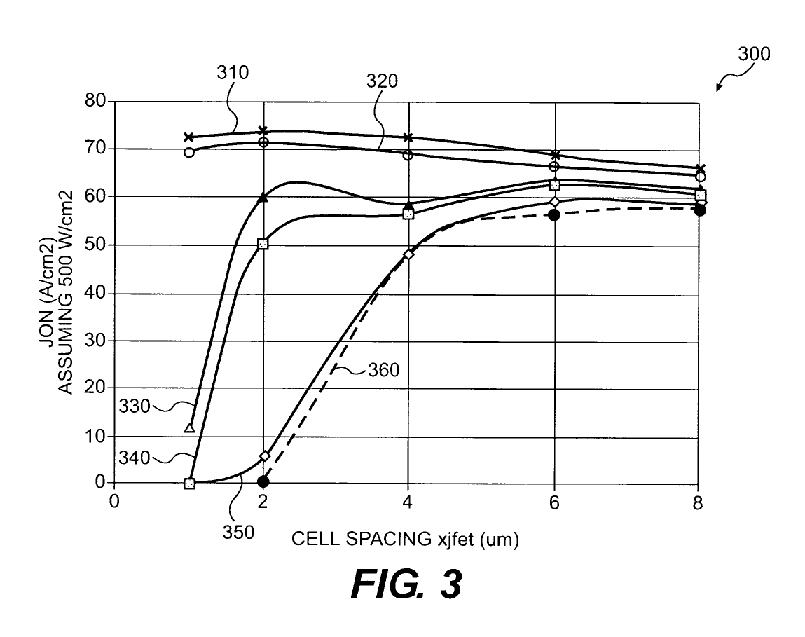

FIG. 3 shows a graph 300 of an on-state current density Jon (A/cm²) versus different cell spacing (xjfet, μm) and current spreading layer dopings (Njfet). Graph 300 shows simulation results based on, for example, a 10 kV IGBT and assuming a package power dissipation limit of 500 W/cm². Current density (J) is a measure of the magnitude of electric current per cross-sectional area. The current density may be measured in amperes per square centimeters (A/cm²). FIG. 3 shows the current density as a function of various doping levels, such as 1×10¹5/cm⁻³ (curve 350), 5×10¹⁵/cm⁻³ (curve 340), 1×10¹⁶/cm⁻³ (curve 330), 5×10¹⁵/cm⁻³ (curve 320), and 1×10¹⁷/cm⁻³ (curve 310), and as a function of various cell spacing xjfet (μm), shown on the x-axis. Curve 360, shown by the dotted line, shows the current density when an enhanced modulation layer is not used. Graph 300 shows that when a higher doped enhanced modulation layer, for example, doped with approximately 5×10¹⁶ cm⁻³ carrier density or more, (see curves 310 and 320) is added to a 10 kV SiC IGBT, smaller cell spacing xjfet, such as from one to three μm, may also result in higher current densities in the on state. Curves 330, 340, 350, indicating a lower doped enhanced modulation layer, or curve 360, indicating that no enhanced modulation layer is used, illustrate that the higher current densities may not be possible until greater cell spacing xjfet exists, thus creating a high electric field at the gate insulator 290 under reverse bias conditions. In one embodiment, the doping of the enhanced modulation layer may be around 5×10¹⁶/cm⁻³, which is approximately 100 times the doping of the n-thick drift layer. Furthermore, the higher doping in the enhanced modulation layer creates less variation in the output current over the various cell spacing (xjfet) than the lower doped or no enhanced modulation layer IGBTs, as shown in FIG. 3. Although FIG. 3 only shows the current density for a 10 kV IGBT and a package power dissipation limit of 500 W/cm², other simulations, with varying IGBT sizes and characteristics, can be performed to reveal other desirable doping concentrations for the enhanced modulation layer and corresponding cell spacing xjfet.

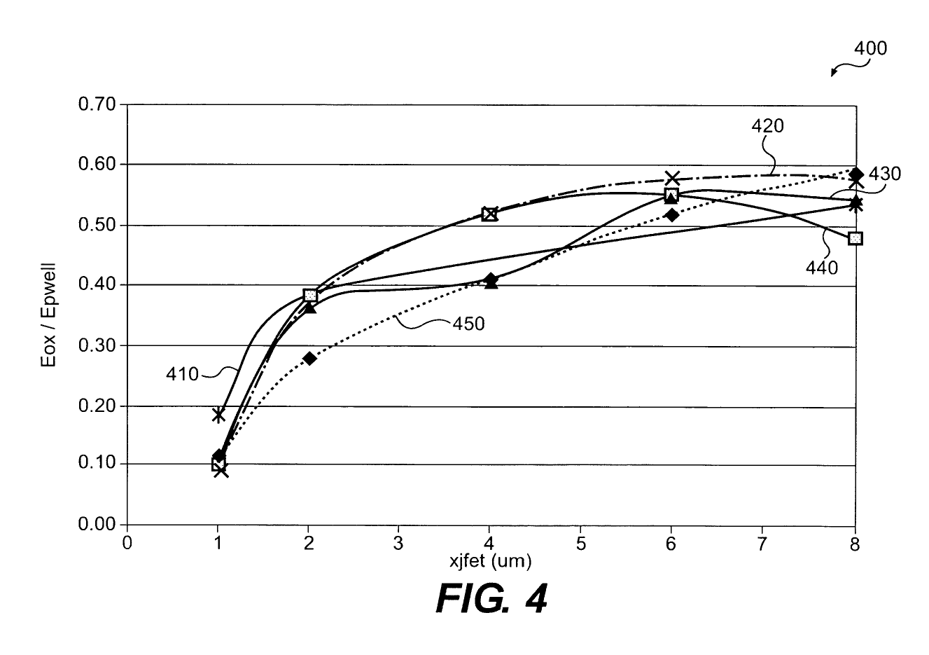

FIG. 4 shows a graph 400 of a ratio (Eox/Epwell) of electric field (E) under the oxide (e.g., a gate insulating film or oxide 190, 290) in the center of the xjfet region (or the cell spacing region) to the electric field at the corner of the p-well (e.g., p well 175, 275 and 276). A low ratio of Eox/Epwell is desirable to keep the electric field in the oxide low under reverse bias. Typical values for oxide electric fields are 2-4 MV/cm to ensure long, reliable operation. The graph shows the ratio Eox/Epwell as a function of various doping levels, such as 5×10¹⁴/cm⁻³ (curve 450), 1×10¹⁵/cm⁻³ (curve 440), 5×10¹⁵/cm⁻³ (curve 430), 1×10¹⁶/cm⁻³ (curve 420), and 5×10¹⁶/cm⁻³ (curve 410), and as a function of various cell spacing xjfet (μm), shown on the x-axis. As can be seen in graph 400, incorporating the enhanced modulation layer in the IGBT, the various curves 410-450 demonstrate that a low electric field at the gate oxide, relative to the high electric field at the p-well corner, can still be on the order of that in an IGBT without the enhanced modulation layer. For example, the ratio Eox/Epwell for an enhanced modulation layer having a doping concentration of 5×10¹⁶/cm⁻³ (410) is approximately 0.2, at a one μm spacing, and the ratio Eox/Epwell for an enhanced modulation layer having a doping concentration of 5×10¹⁴/cm⁻³ is approximately 0.1, at a one μm spacing.

From FIGS. 3 and 4, it can be seen that a IGBT structure with an enhanced modulation layer with various dopings and cell spacing can be designed, such that the IGBT device has improved on-state characteristics and low electric field at the gate oxide.

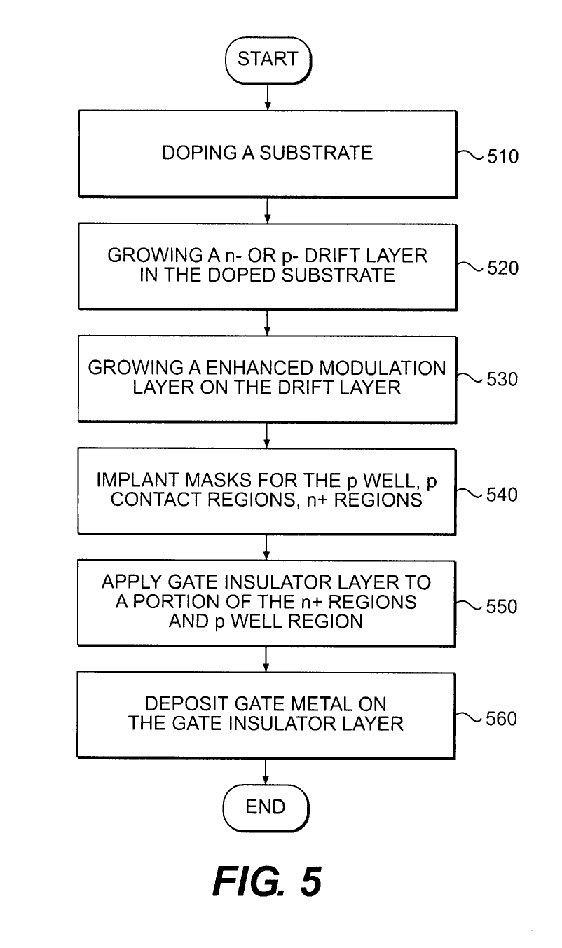

FIG. 5 is a flow chart illustrating the fabrication process for an enhanced modulation layer IGBT in accordance with an embodiment. The enhanced modulation layer IGBT fabrication step begins with an n+ substrate doped typically around 1×10¹⁸/cm⁻³, as shown in FIG. 1. A n- or p-drift layer is grown in the doped substrate, as shown in 520. A n+ buffer layer may be grown on top of the substrate followed by a thick n-drift layer for a punch-through device, or the thick n-drift layer can be grown on top of the substrate for a non-punch-through device.

In accordance with an embodiment, an enhanced modulation layer is then grown on top of the N-drift layer, as shown in 530. The enhanced modulation layer may be grown as an epitaxial layer, such as in SiC processing, or by deep diffusion, such as in Si processing. Optionally or additionally, a chemical mechanical polish may be applied to the surface of the substrate to enhance the device channel characteristics.

Following the enhanced modulation layer growth and surface preparation, photolithography is used to pattern the implant masks for the p well, p contact regions, and n+ regions, as shown in 540. In addition, photolithography may also be used to pattern the implant masks for edge termination and/or field stop areas. After implantation, an activation anneal is performed to electrically activate the dopants. Once the dopants are activated, an epitaxial layer may be grown on top of the surface at about 100-400 Angstroms(Å), for example, to provide a MOS channel region that does not have implant damage. If this epitaxial regrowth region is used, it can then be patterned to be slightly larger than the gate region, but able to leave the n+ and p well open for metal contacts.

A gate insulator layer, such as SiO₂, may be applied by oxidation or growth/deposition to a portion of n+ and p well regions, as shown in 550. The gate insulator layer may be etched back to be slightly larger than the gate region, but portions of the N+ and P well regions are left open for metal contacts. Following the gate insulator layer, the gate metal is deposited, as shown in 560. The gate metal may be a poly-silicon, molybdenum, or any other metal used for standard MOS devices. The gate metal layer is patterned to form the gate region. Following the gate region deposition, silicide may be patterned and deposited on the p well and n+ regions, as well as on the gate material. Passivation is then grown or deposited, followed by a thick overlay metal for current handling.

An embodiment of the present invention provides a transistor, such as a bipolar electronic power device, having an enhanced modulation layer that may be manufactured using SiC, Si or other material. This enhanced modulation bipolar power device may offer reduced on-state power dissipation as compared to conventional unipolar devices such as MOSFETs or SITs, and may provide better conductivity modulation than conventional SiC IGBTs. By using an enhanced modulation layer with optimal doping and spacing, enhanced modulation in the IGBT base is produced.

Several embodiments of the present invention are specifically illustrated and/or described herein. However, it will be appreciated that modifications and variations of the present invention are covered by the above teachings and within the purview of the appended claims without departing from the spirit and intended scope of the invention.

What is claimed is:

1. A n-type insulated gate bipolar transistor (IGBT) device comprising: a emitter, collector, and gate;
a p+ doped injecting layer coupled to the emitter;
a n− doped drift layer disposed on the p+ doped injecting layer;
a first p well body region disposed on the n− doped drift layer, wherein the n− doped drift layer is located between the p+ doped injecting layer and the first p well body region;
a n+ region disposed in the first p well body region, wherein the gate is disposed over a portion of the first p well body region with a gate insulating film interposed there between and wherein the collector is in contact with the n+ region and a portion of the first p well body region; and
an enhanced modulation layer disposed within a portion of the n− doped drift layer, wherein the enhanced modulation layer contains a higher carrier concentration than the n− doped drift layer and if the IGBT device is in an on state, the enhanced modulation layer decreases a size of a depletion region formed around the first p well body region, and electrons, traveling from the n+ region towards the emitter, are spread laterally and uniformly in the n− doped drift layer.

2. The IGBT device of claim 1, wherein the enhanced modulation layer surrounds the first p well body region.

3. The IGBT device of claim 1., further comprising: a n+ doped buffer layer, wherein the n+ doped buffer layer is disposed between p+ doped injecting layer and the n− doped drift layer.

4. The IGBT device of claim 1, wherein the gate is disposed over a portion of the enhanced modulation layer with the gate insulating film interposed there between.

5. The IGBT device of claim 1, wherein the laterally and uniformly spread electrons attract holes injected from the p+ doped injecting layer and the injected holes are spread laterally and uniformly in the n− doped drift layer and wherein on resistance of the IGBT device is reduced.

6. The IGBT device of claim 1, further comprising:
a second p well body region, wherein the enhanced modulation layer surrounds the first and second p well body regions and a horizontal distance between the first and second p well body regions is between 0.5 to 3 micron meters.

7. The IGBT device of claim 1, wherein the carrier concentration of the enhanced modulation layer is between 1×10¹⁵/cm³ and 1×10¹⁷/cm³.

8. The IGBT device of claim 1, wherein the n− doped drift layer comprises one or more of silicon carbide or silicon.

9. A p-type insulated gate bipolar transistor (IGBT) device comprising:
a emitter, collector, and gate;
a n+ doped injecting layer coupled to the emitter;
a p− doped drift layer disposed on the n+ doped injecting layer;
a first n well region disposed on the p− doped drift layer, wherein the p− doped drift layer located between the n+ doped injecting layer and the first n well region;
a p+ region disposed in the first n well region, wherein the gate is disposed over a portion of the first n well region with a gate insulating film interposed there between and wherein the collector is in contact with the p+ region and a portion of the first n well region; and
an enhanced modulation layer disposed within a portion of the p− doped drift layer, wherein the enhanced modulation layer contains a higher carrier concentration than the p− doped drift layer and if the IGBT device is in an on state, the enhanced modulation layer decreases a size of a depletion region formed around the first n well region, and holes, traveling from the p+ region towards the emitter, are spread laterally and uniformly in the p− doped drift layer.

10. The IGBT device of claim 9, wherein the enhanced modulation layer surrounds the first n well region.

11. The IGBT device of claim 9, further comprising:
a p+ doped buffer layer, wherein the p+ doped buffer layer is disposed between n+ doped injecting layer and the p− doped drift layer.

12. The IGBT device of claim 9, wherein the gate is disposed over a portion of the enhanced modulation layer with the gate insulating film interposed there between.

13. The IGBT device of claim 9, wherein the laterally and uniformly spread holes attract electrons injected from the n+ doped injecting layer and the injected electrons are spread laterally and uniformly in the p− doped drift layer and wherein on resistance of the IGBT device is reduced.

14. The IGBT device of claim 9, further comprising:
a second n well region, wherein the enhanced modulation layer surrounds the first and second n well regions and a horizontal distance between the first and second n well regions is between 0.5 to 3 micron meters.

15. The IGBT device of claim 9, wherein the carrier concentration of the enhanced modulation layer is between 1×10¹⁵/cm³ and 1×10¹⁷/cm³.

16. The IGBT device of claim 9, wherein the p− doped drift layer comprises one or more of silicon carbide or silicon.

17. A method for fabricating a bi-polar transistor having an enhanced modulation layer, the method comprising:
growing a drift layer region on a doped substrate; growing an enhanced modulation layer in the drift layer region of the bi-polar transistor;
implanting p well regions; and
implanting n+ regions in the p well regions.

18. A method of claim 17, wherein the carrier concentration of the enhanced modulation layer is between 1×10¹⁵/cm³ and 1×10¹⁷/cm³.

19. A method of claim 17, further comprising:
implanting p well regions for a multi-cell bi-polar transistor surrounded by the enhanced modulation layer, wherein the enhanced modulation layer surrounds first and second p well body regions of consecutive cells and a horizontal distance between the first and second p well body regions is between 0.5 to 3 micron meters.

20. The method of claim 17, wherein if the enhanced bi-polar transistor device is in an on state, the enhanced modulation layer decreases a size of a depletion region formed around the p well regions, and electrons, traveling from the n+ region towards a emitter, are spread laterally and uniformly in the drift layer.

21. A method for fabricating a bi-polar transistor having an enhanced modulation layer, the method comprising:
growing a drift layer region on a doped substrate;
growing an enhanced modulation layer in the drift layer region of the bi-polar transistor;
implanting n well regions; and
implanting p+ regions in the n well regions.

22. A method of claim 21, wherein the carrier concentration of the enhanced modulation layer is between 1×10¹⁵/cm³ and 1×10¹⁷/cm³.

23. A method of claim 21, further comprising:
implanting n well regions for a multi-cell bi-polar transistor surrounded by the enhanced modulation layer, wherein the enhanced modulation layer surrounds first and second n well regions of consecutive cells and a horizontal distance between the first and second n well regions is between 0.5 to 3 micron meters.

24. The method of claim 21, wherein if the enhanced bi-polar transistor device is in an on state, the enhanced modulation layer decreases a size of a depletion region formed around the n well regions, and holes, traveling from the p+ region towards a emitter, are spread laterally and uniformly in the drift layer.
